(19) United States
(12) Patent Application Publication
(10) Pub. No.: US 2026/0088827 A1
(43) Pub. Date: Mar. 26, 2026

(54) High Voltage Delta-Sigma Modulator Analog-to-Digital Converter

(71) Applicant: Cypress Semiconductor Corporation, San Jose, CA (US)

(72) Inventors: Lukang Shi, Snohomish, WA (US); Rajiv Singh, Bothell, WA (US); David Goniodsky, Kirkland, WA (US); Liam Feeney, Cork (IE); Erhan Hancioglu, Shoreline, WA (US); Katsuyuki Yasukouchi, Aichi (JP); Masashi Kijima, Aichi (JP)

(73) Assignee: Cypress Semiconductor Corporation, San Jose, CA (US)

(21) Appl. No.: 18/894,436

(22) Filed: Sep. 24, 2024

(51) Int. Cl. H03M 3/00; G01R 31/3835; G01R 31/396; H01M 10/42; H01M 10/48; H01M 50/51; H02M 3/07

(52) U.S. Cl. CPC H03M 3/458; G01R 31/3835; G01R 31/396; H01M 10/425; H01M 10/482; H01M 50/51; H03M 3/422; H01M 2010/4271; H02M 3/07

(57) ABSTRACT

A Delta-Sigma-Modulator (DSM) Analog-to-Digital Converter (ADC) and method of operating the same are provided. Generally, the ADC includes an input stage to receive an analog input voltage, a second order DSM coupled to the input stage, the DSM including a first integrator stage and a second integrator stage coupled in a cascade architecture, and a quantizer coupled to an output of the DSM operable to receive an output therefrom and to produce a multi-bit digital signal. The ADC has a fully differential architecture with the input stage coupling a positive input voltage and a negative input voltage to an integrator in the first integrator stage, the first integrator stage coupling a first positive output signal and a first negative output signal to a second integrator in the second integrator stage, and the second integrator stage coupling a second positive output signal and a second negative output signal to the quantizer.

### TECHNICAL FIELD

This disclosure relates generally to Analog-to-Digital Converters (ADCs) for battery management system applications, and more particularly to High Voltage Delta-Sigma Modulator ADCs (ΔΣADCs) and methods of operating the same.

### BACKGROUND

An analog-to-digital converter (ADC) is an electronic or device circuit that converts an analog voltage or waveform into a discrete digital representation or sequence. ADCs are essential elements or blocks of many devices and systems, including, for example, battery monitoring or management systems (BMS) used in battery powered electrical vehicles. There are several different types of conventional ADCs that may be used in these applications, including integrating ADCs, successive approximation register (SAR) ADCs and Delta-Sigma ADCs. Other types of high speed ADCs exist, such as flash and pipeline ADCs, however cost constraints, power requirements, and size, where the ADCs are included in integrated circuits (IC), limit their usefulness in many mobile applications including automotive and portable wireless devices.

In addition there are a number of problems with existing or conventional ADCs including having an insufficient effective number of bits (ENOB), and Electromagnetic compatibility (EMC) issues, such as susceptibility to electromagnetic interference (EMI) due to the unintentional generation, propagation and reception of electromagnetic energy in the environment in which they are used.

The ENOB specifies the number of bits an ADC requires to effectively represent an analog value, and is commonly used as a quality measure of the resolution and dynamic range of the ADC. Ideally, a 16-bit ADC will have an ENOB of nearly 16. However, due to noise and distortion introduced by imperfect components in the ADC and a system in which it is used, the effective number of bits of accuracy in the real ADC will be substantially lower. Thus, a 16-bit ADC may have an ENOB of 12 or less.

Accordingly, there is a need for an improved ADC and methods of operating the same to increase ENOB, while reducing susceptibility to EMI issues as well as power demands. It is further desirable that the new ADC meet size and cost requirements for use in mobile applications.

### SUMMARY

Disclosed is a Delta-Sigma-Modulator Analog-to-Digital Converter (ΔΣADC) and method of operating the same to increase the effective number of bits (ENOB), while reducing susceptibility to EMI issues as well as power demands. The ΔΣADC includes an input stage operable to receive an analog input voltage (V_{IN}), a second order Delta-Sigma-Modulator (2^{nd} order DSM) coupled to the input stage, the DSM including a first integrator stage and a second integrator stage coupled in a cascade architecture, and a quantizer coupled to an output of the DSM operable to receive an output therefrom and to produce a multi-bit digital signal. The ΔΣADC has a fully differential architecture with the input stage coupling a positive input signal (inp) and a negative input signal (inn) to an integrator in the first integrator stage, the first integrator stage coupling a first positive output signal (op1) and a first negative output signal (on1) to a second integrator in the second integrator stage, and the second integrator stage coupling a second positive output signal (op2) and a second negative output signal (on2) to the quantizer. The fully differential architecture enables the ΔΣADC to minimize potential Electromagnetic compatibility (EMC) issues.

Generally, the input stage and first integrator stage are operable to perform correlated double sampling on the positive input signal (inp) and the negative input signal (inn) to remove any undesired offset in analog input voltage (V_{IN}). Additionally, the first integrator stage further includes a number of chopping circuits operable to remove any residual offset in V_{IN}.

In some embodiments, the input stage includes a high-voltage-interface (HVIF) to enable the ΔΣADC to support voltages of 120 VDC or more.

The ΔΣADC is particularly useful in an integrated battery management system (BMS) configured to monitor voltages of a plurality of battery cells connected in series.

Further features and advantages of embodiments of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to a person skilled in the relevant art(s) based on the teachings contained herein.

### BRIEF DESCRIPTION OF THE DRAWINGS

Embodiments of the invention will now be described, by way of example only, with reference to the accompanying schematic drawings in which corresponding reference symbols indicate corresponding parts. Further, the accompanying drawings, which are incorporated herein and form part of the specification, illustrate embodiments of the present invention, and, together with the description, further serve to explain the principles of the invention and to enable a person skilled in the relevant art(s) to make and use the invention.

FIG. 1 is a schematic diagram illustrating an embodiment of a second order delta-sigma modulator analog-to-digital converter (ΔΣADC);

FIG. 2 is a timing diagram illustrating various signal for operation of the ΔΣADC of FIG. 1;

FIG. 3 is a flowchart illustrating a method for operating the ΔΣADC of FIG. 1;

FIGS. 4A and 4B are graphs comparing idle tone of a ΔΣADC with a first order DSM and an ΔΣADC with a second order DSM;

FIGS. 5A-5C are graphs illustrating the idle tone of a second order DSM with a 20 μV input step size for various oversampling ratios (OSR);

FIG. 6A is a block diagram illustrating an embodiment of a High Voltage Interface (HVIF) for use in the ΔΣADC of FIG. 1;

FIG. 6B is schematic diagram illustrating an embodiment of one side or half of the HVIF of FIG. 6A;

FIG. 7A is a timing diagram illustrating operation of the HVIF of FIGS. 6A and 6B in the ΔΣADC of FIG. 1 for a battery voltage V_{BAT} in of 5V;

FIG. 7B is a timing diagram illustrating operation of the HVIF of FIGS. 6A and 6B in the ΔΣADC of FIG. 1 for a battery voltage V_{BAT} in of −2V;

FIG. 8 a schematic block diagram illustrating charge-pump outputs for the HVIF of FIGS. 6A and 6B operating at V_{BAT} of 5V and −2V; and

FIG. 9 is a block diagram illustrating a battery management system (BMS) including a number of the ΔΣADCs of FIG. 1.

### DETAILED DESCRIPTION

A switched capacitor Delta-Sigma-Modulator Analog-to-Digital Converter (ΔΣADC) and method of operating the same to convert or provide output a multi-bit binary-number approximating an analog input voltage (V_{IN}) is disclosed. The ΔΣADC and method of the present disclosure provide a high effective number of bits (ENOB) and throughput, while minimizing potential electromagnetic compatibility (EMC) issues and reducing area required for implantation in an integrated circuit (IC), making the ΔΣADC particularly useful in an integrated battery management system (BMS) configured to monitor voltages of a plurality of battery cells connected in series.

Generally, the ΔΣADC includes an input stage operable to receive an analog input voltage (V_{IN}), a second order Delta-Sigma-Modulator (2^{nd} order DSM) coupled to the input stage, the DSM including a first integrator stage and a second integrator stage coupled in a cascade architecture, and a quantizer coupled to an output of the 2^{nd} order DSM operable to receive an output therefrom and to produce a multi-bit digital signal. The ΔΣADC has a fully differential architecture with the input stage coupling a positive input signal (inp) and a negative input signal (inn) to an integrator in the first integrator stage, the first integrator stage coupling a first positive output signal (op1) and a first negative output signal (on1) to a second integrator in the second integrator stage, and the second integrator stage coupling a second positive output signal (op2) and a second negative output signal (on2) to the quantizer. The fully differential architecture enables the ΔΣADC to minimize potential EMC issues.

In some embodiments, the input stage and first integrator stage are operable to perform correlated double sampling on the positive input signal (inp) and the negative input signal (inn) to remove an offset in V_{IN}. Additionally, the first integrator stage further includes a chopping circuit operable to operable to remove any residual offset in V_{IN} coupled from the input stage to the first integrator stage.

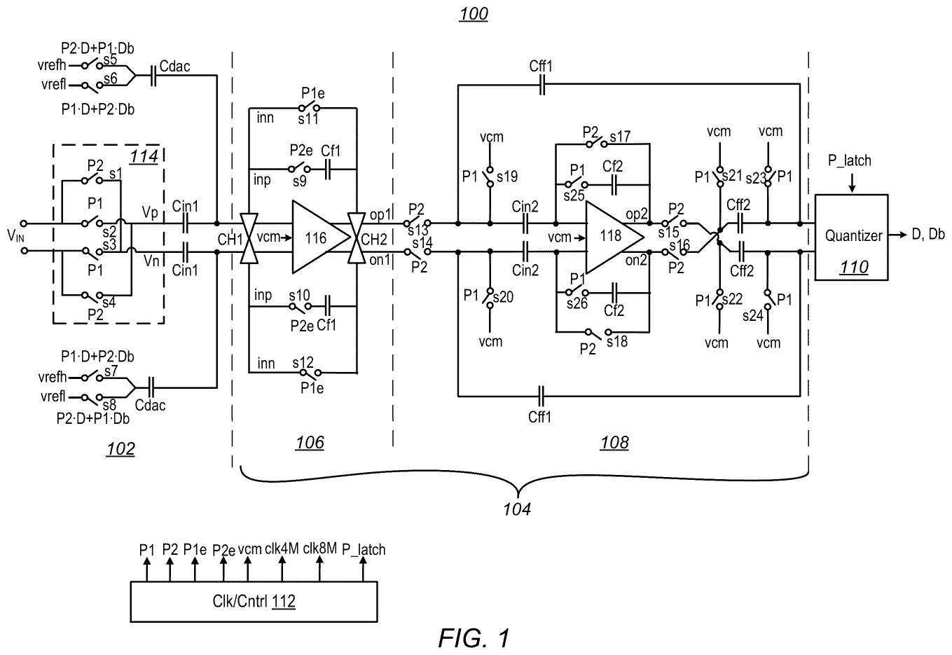

Embodiments of the ΔΣADC and methods for operating the same will now be described in greater detail with reference to FIGS. 1 through 5.

FIG. 1 is a schematic diagram illustrating an embodiment of a second order delta-sigma modulator analog-to-digital converter (ΔΣADC). Referring to FIG. 1 the ΔΣADC 100 includes an input stage 102 operable to receive an analog input voltage (V_{IN}), a second order delta-sigma-modulator (2^{nd} order DSM 104) including a first integrator stage 106 and a second integrator stage 108 coupled in a cascade architecture, and a quantizer 110 coupled to the output of the 2^{nd} order DSM operable to produce and output a multi-bit digital signal. The ΔΣADC 100 further includes a sampling clock and control circuit (Clk/Cntrl 112), to control operation of switches in the ΔΣADC and a chopping circuit.

The input stage 102 includes an input interface 114 including a pair of sampling or first input capacitors (Cin1) with input nodes coupled to input terminals through sampling switches (S1, S2, S3, S4) to receive V_{IN}. Switches S1, S2, S3, and S4 are controlled by P1 and P2 signals from the Clk/Cntrl 112. The input stage 102 further includes a pair of digital to analog converter (DAC) capacitors (C_{DAC}) having input nodes alternately coupled to a high reference voltage (Vrefh) and a low reference voltage (Vrefl) through reference switches (S5, S6, S7, S8), and output nodes coupled to output nodes of the first input capacitors (Cin1) and to input nodes of the and first integrator stage 106 in the 2^{nd} order DSM 104.

Switches S6 and S7 are turned on or closed by a product of a first signal P1 of the sampling clock (Clk/Cntrl 112), and results of a previous quantization (D), and turned off or opened by a product of a second signal P2 of the sampling clock and results of a subsequent quantization (Db). Similarly, switches S5 and S7 turned on by a product of the second signal P2 and results of a previous quantization (D), and turned off by a product of the first signal P1 and results of a subsequent quantization (Db). The differential between reference voltages Vrefl and Vrefh define a range of valid V_{IN} inputs to the ΔΣADC 100.

The first integrator stage 106 includes a first integrator 116 with fully differential outputs, and a common mode voltage input (vcm) to isolate the first integrator from variations in a common mode voltage in V_{IN}. The first integrator stage 106 further includes a chopping circuit pair CH1/CH2 coupled between the inputs and outputs of the first integrator 116, and first integration or feedback capacitors (Cf1) coupled in series with feedback switch (S9, S10) between each input and an associated output, and reset switches (S11, S12) coupled in parallel with the feedback capacitors (Cf1) and feedback switches (S9, S10). The feedback switches (S9, S10) are operated by a second signal P2e, where ‘e’ stands for early meaning this signal come slightly before clock P2 from the sampling clock (Clk/Cntrl 112) to turn on or close to begin integration, and the reset switches (S11, S12) are operated by a first P1 early signal (P1e) to reset the first integrator 116 following a sampling or integration operation.

The first integrator 116 is operable to calculate the integral of input voltage signals (Vp, Vn), and output signals (op1, on1) reflecting the cumulative effect of the input voltage signals (Vp, Vn), over time. As noted above, the fully differential architecture of the first integrator stage 106 minimize potential Electromagnetic compatibility (EMC) issues. Additionally, the fully differential architecture and common mode voltage input (vcm) of the first integrator 116 substantially cancel any offset of the first integrator while the chopping circuit pair CH1/CH2 removes any residual offset from the output signals (op1, on1).

The second integrator stage 108 is coupled in cascade with the first integrator stage 106 through first stage output switches (S13, S14) turned on by the second signal from the sample clock (Clk/Ctrl 112). The second integrator stage 108 includes a pair of second input capacitors (Cin2), a second integrator 118 with fully differential outputs, a pair of first feedforward capacitors (Cff1) coupled between input nodes and output nodes of the second integrator stage 108, and a pair of second feedforward capacitors (Cff2) coupled between outputs of the second integrator and outputs of the second integrator stage through output switches (S15, S16) turned on by second signal from the sample clock (Clk/Ctrl 112). The second integrator stage 108 further includes second integration or feedback capacitors (Cf2) coupled in parallel with reset switches (S17, S18) between each input through switches (S25, S26) and an associated output of the second integrator 118. The reset switches (S17, S18) are turned on by a reset signal (RST) from the sample clock (Clk/Ctrl 112) following a complete conversion of the analog input voltage to a multibit binary output signal (D, Db).

The second integrator stage 108 further includes a number of common mode voltage switches (S19-S24) coupling input and output nodes of the second input capacitors (Cin2) and the second feedforward capacitors (Cff2) to the common mode voltage to reset these capacitors between integration operations. In particular, second stage input switches (S13, S14) are turned on by a second signal (P2) from the sample clock (Clk/Ctrl 112) to enable integration of the first output signals (op1, on1) in the second integration stage 108, and common mode voltage switches S19, S20, S21, S22, S23 and S24, are turned on by the first signal (P1 the sample clock to reset the second integration stage 108 for the integration of subsequent signals from the first integration stage 106.

The quantizer 110 is coupled to the output of the 2^{nd} order DSM 104, and is operable to receive second positive and negative output signals (op2, on2) reflecting the cumulative effect of the first output signals (op1, on1), over time from the second integrator 118 and to produce a multi-bit digital signal (D, Db).

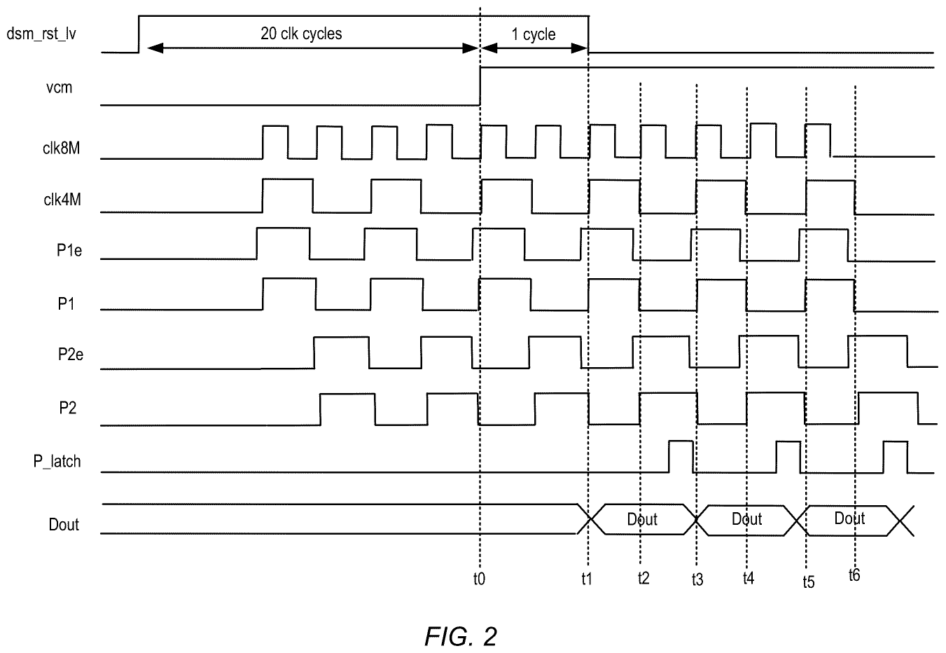

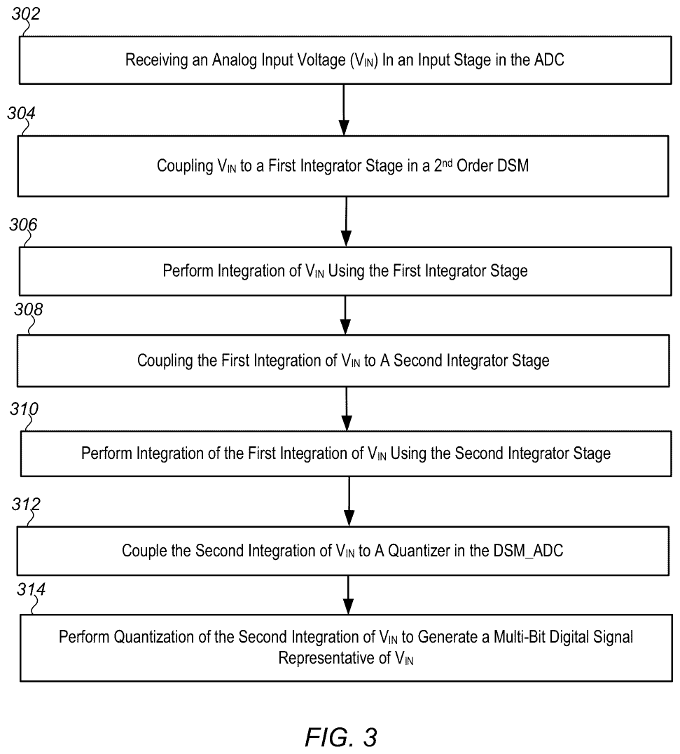

Operation of the ΔΣADC 100 of FIG. 1 will now be described with reference to FIGS. 2 and 3, where FIG. 2 is a timing diagram of various signals generated by the ΔΣADC of FIG. 1, and FIG. 3 is a flowchart illustrating a method for operating the ΔΣADC.

Referring to FIG. 2, prior to time t0 a reset signal (dsm_rst_lv) is applied for about 20 clock cycles to reset switches (S17, S18) in the second integrator stage 108 to reset second integrator 118 and feedback capacitors (Cf2). At time t0 a vcm input (vcm_good_lv) is applied to the first and second integrators 116, 118.

Referring to FIG. 3 the method begins with receiving an analog input voltage (V_{IN}) in an input stage in the ADC (step 302), and at time t1 applying signal P1 to switches S2 and S3 to couple V_{IN} to a first integrator stage in a 2^{nd} order DSM (step 304). From time t1 to t3 the positive component of V_{IN} (Vp) and the negative component of V_{IN} (Vn) are coupled from the input stage to the 2^{nd} order DSM and is integrated at time t2 using the first integrator stage with a signal from the sample clock (Clk/Ctrl 112) (step 306). The signal from the sample clock can include either a 4 MHz signal (clk4M) from the sampling clock and control circuit (Clk/Cntrl 112), as shown in FIG. 1, or another main clock frequency, for example 5 MHz. As shown and described above with reference to FIG. 1, the ΔΣADC has a fully differential architecture so that at a time immediately prior to t1 signal P1e applied to switches S11 and S12 enable integration of negative input signal (inn), and at a time immediately prior to t2 switches S11 and S12 are opened and signal P2e is applied to switches S9 and S10 to enable integration of positive input signal (inp). Additionally, in some embodiments, such as that shown in FIG. 1, the first integrator stage 106 further includes a chopping circuit CH1/CH2, thus coupling V_{IN} to the first integrator stage 116 includes operating the chopping circuit to remove any residual offset in V_{IN} coupled from the input stage to the first integrator stage.

Next, results of the first integration of V_{IN} by the first integrator stage 106 are coupled to a second integrator stage in the 2^{nd} order DSM connected to the first integrator stage with a cascade architecture (step 308). Coupling the first integration of V_{IN} to the second integrator stage includes coupling a first positive output signal (op1) and a first negative output signal (on1) to a second integrator in the second integrator stage by applying signal P2 to switches S13 and S14. The first integration of V_{IN} coupled from the first integration stage is then integrated using the second integrator stage with the sampling clock to generate a second integration of V_{IN} (step 310). That is signal P2 applied to switches S17 and S18 enables a second or further integration of on1, and immediately following which switches S17 and S18 are opened and signal P1 is applied to switches S25 and S26 to enable a second or further integration of op1. At this time signal P1 is also applied to switches S19 and S20 to couple vcm signals to isolate variations in common mode voltage from input sides of capacitors Cin2.

Next, the second integration of V_{IN} is coupled from an output of the 2^{nd} order DSM to a quantizer in the ΔΣADC (step 312), and quantization of the second integration of V_{IN} performed to generate a multi-bit digital signal representative of V_{IN} (step 314). Coupling the second integration of V_{IN} to the quantizer includes coupling a second positive output signal (op2) and a second negative output signal (on2) to the quantizer through capacitors cff2 by applying signal p2 to switches S15 and S16. At this time signal P1 is applied to switches S21 to S24 to couple vcm signals to isolate variations in common mode voltage from capacitors Cff2 and the quantizer. Generally, as note above the first integrator 116 and the second integrator 118 also each include a common mode voltage (vcm) input, to isolate variations in common mode voltage in V_{IN} from the output (op2 and on2) to the quantizer 110. The output of the quantizer 110 is latched by application of a p_latch signal to store a first, most significant bit (MSB) or digit (D) of a multi-bit digital signal. The p_latch signal is generated using an 8 MHz signal (clk8M) from the Clk/Cntrl 112 and has pulse with duty cycle equal to quarter of the main sample clock (clk4M) signal. The digit (D) is applied in conjunction with signals P1 and P2 to operate switches S5-S7 to alternately apply high (Vrefh) and low reference voltages (Vrefl) capacitors C_{DAC} having to prepare the 100 for conversion of the next MSB of the multi-bit digital signal beginning at time t3. The process continues until a final bit or digit of the multi-bit digital signal, i.e., digit Db, has been resolved.

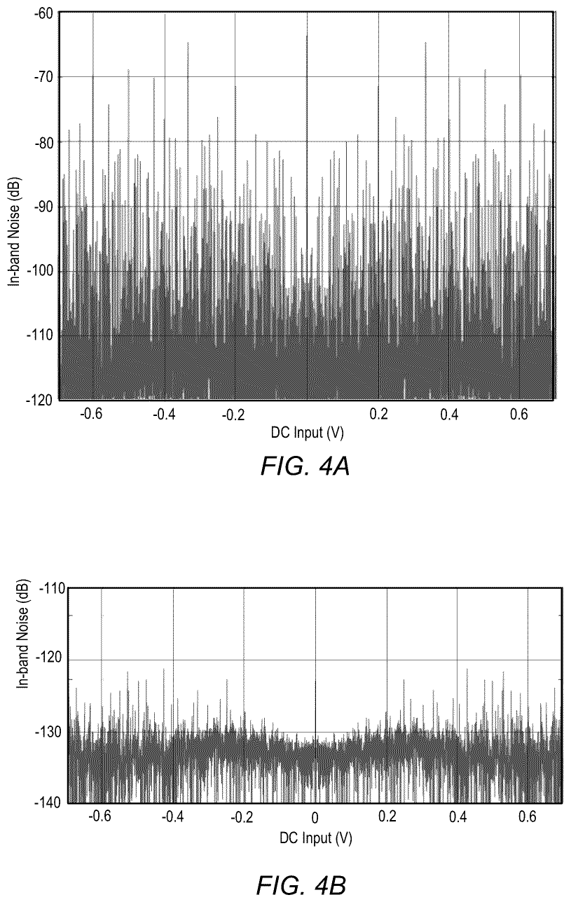

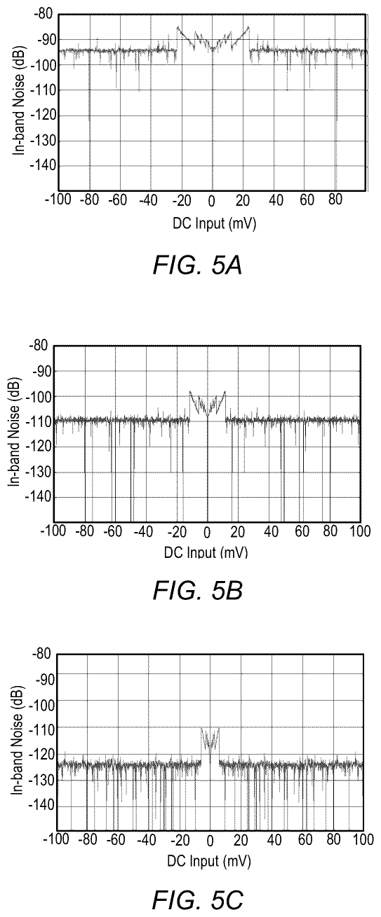

The advantages of a 2^{nd} order DSM in a ΔΣADC will now be described with reference to FIGS. 4A-4B and 5A through 5C.

FIGS. 4A and 4B are graphs comparing idle tone or quantization noise for a ΔΣADC with a single, first order DSM, and a ΔΣADC with a 2^{nd} order DSM, such shown and described above with reference to FIG. 1. Data for both graphs was obtained using MATLAB software simulating ΔΣADCs with a 1-bit quantizer and operating at an oversampling rate or ratio (OSR) of 1024. Referring to FIG. 4A it is seen that for a ΔΣADC including a single, 1^{st} order DSM, the ΔΣADC has an in-band noise as high as about −65 dB. In contrast, referring to FIG. 4B it is seen that for a ΔΣADC including a 2^{nd} order DSM, the ΔΣADC has a maximum in-band noise of less than about −120 dB.

FIGS. 5A-5C are graphs illustrating the idle tone for a ΔΣADC with a 2^{nd} order DSM and a simulated 20 μV input step size for various OSRs. FIG. 5A illustrates the in-band noise for a ΔΣADC with a 2^{nd} order DSM operating at an OSR of 128, FIG. 5B illustrates the in-band noise for a ΔΣADC with a 2^{nd} order DSM operating at an OSR of 256, and FIG. 5C illustrates the in-band noise for a ΔΣADC with a 2^{nd} order DSM operating at an OSR of 512. Thus, it is seen that for a ΔΣADC with a 2^{nd} order DSM, such shown and described above with reference to FIG. 1, idle tone is becomes smaller and narrower when operated with larger OSRs.

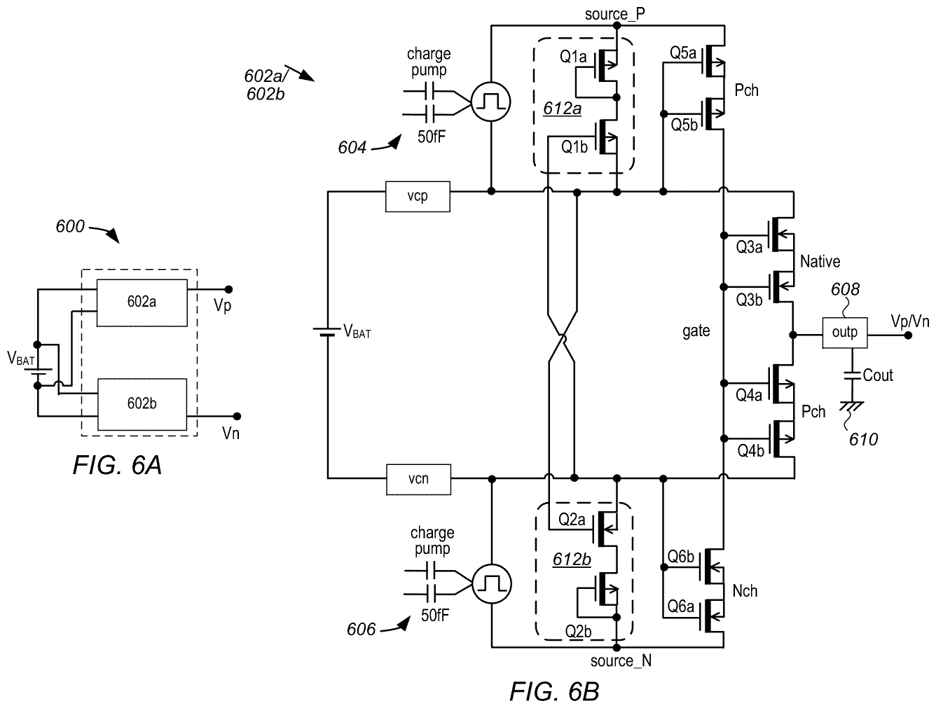

In some embodiments, shown in FIGS. 6A and 6B, the input interface 114 of FIG. 1 is replaced with a High Voltage Interface (HVIF 600) to attenuate and level shift an input voltage or battery voltage (V_{BAT}), enabling the ΔΣADC 100 to support negative differential input voltages, and voltages of up to 120V absolute voltage. FIG. 6A is a block diagram illustrating an embodiment of the HVIF 600. Referring to FIG. 6A the HVIF 600 generally includes a positive or Vp half HVIF 602a coupled between V_{BAT} or V_{IN} and a Vp node of the first integrator 116, and a negative half HVIF 602b coupled between V_{BAT} or V_{IN} and a Vn node of the first integrator. Each of the halves of the HVIF 602a and 602b are substantially identical and will now be described with reference to FIG. 6B. FIG. 6B is a schematic diagram illustrating an embodiment of one side or half of the HVIF 602a, 602b, the HVIF 600.

Referring to FIG. 6B the half HVIF 602a, 602b, includes a first charge-pump 604 having a first or charge-pump input node coupled to a positive voltage input (vcp) of the HVIF and a second or charge-pump output node coupled to a positive source voltage node (source_P), and a second charge-pump 606 having a first charge-pump input node coupled to a negative voltage input (vcn) of the HVIF and a second or charge-pump output node coupled to a negative source voltage node (source_N). Source_P is equal to a sum of vcp and an output of the first charge-pump 604, and Source_N is equal to a sum of vcn and an output of the second charge-pump 606. The half HVIF 602a, 602b, further includes an output stage 608, a limiter circuit, in parallel with the first and second charge-pumps 604, 606, and an output node (outp) coupled between the output stage and, through an output capacitor (Cout), to virtual node or ground 610 of the integrator.

The limiter circuit includes a first portion 612a having a first diode-connected transistor (Q1a) coupled in series with a second transistor (Q1b) between source_P and vcp, and a second portion 612b having a first diode-connected transistor (Q2a) coupled in series with a second transistor (Q2b) between source_N and vcn. A gate of the second transistor Q1b in the first portion 612a of the limiter circuit is coupled to vcn, and a gate of the gate of the second transistor Q2b in the second portion 612b of the limiter circuit is coupled to vcp.

The output stage 608 includes a first pair of series connected transistors (Q3a, Q3b) coupled in series with a second pair of series connected transistors (Q4a, Q3b) between vcp and vcn in a or source-follower configuration, the output node (outp) coupled between the common drains of the first and second pairs of transistors. Gates of t transistors (Q3a, Q3b, Q4a, Q4b) are coupled between source_P of the first charge-pump 604 through a pair of series connected transistors (Q5a, Q5b), and source_N of the second charge-pump 606 through another pair of series connected transistors (Q6a, Q6b).

In order to minimize any increase layout area for the ΔΣADC 100, the HVIF 600 can be implemented using only 5V devices, and configured or operable to receive an input or battery voltage (V_{BAT}) a range of −2V to +5V.

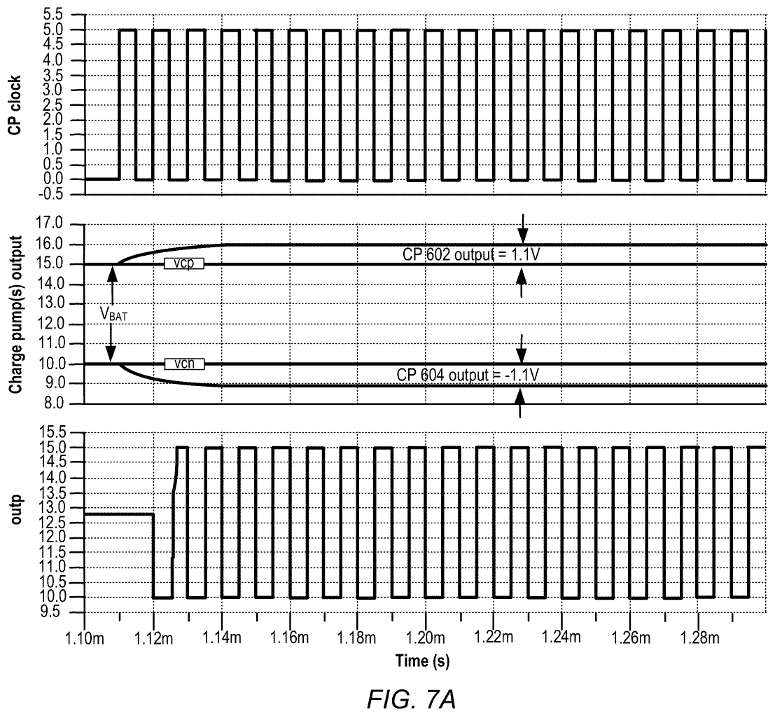

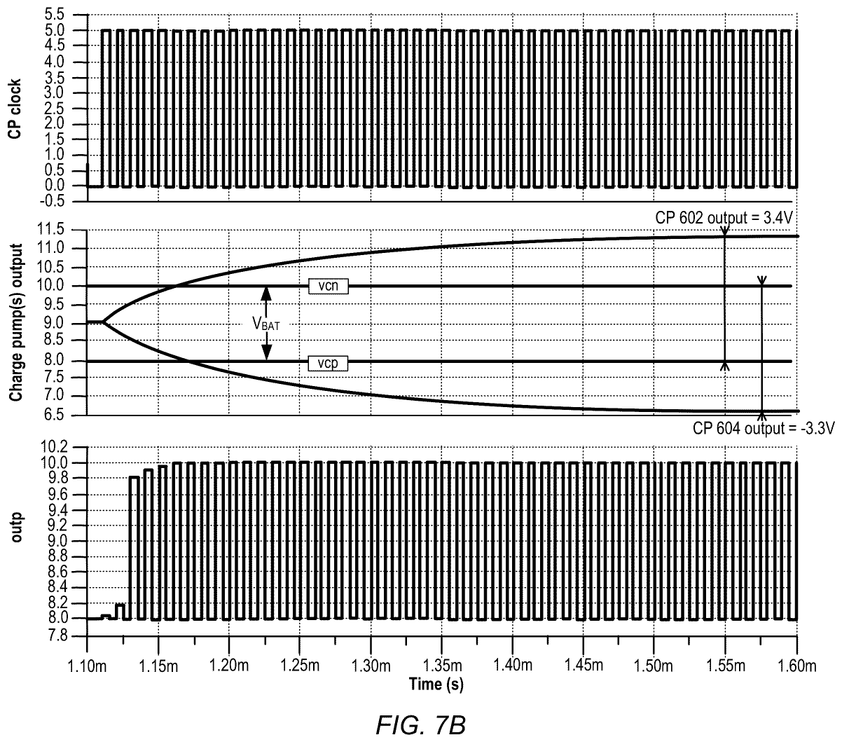

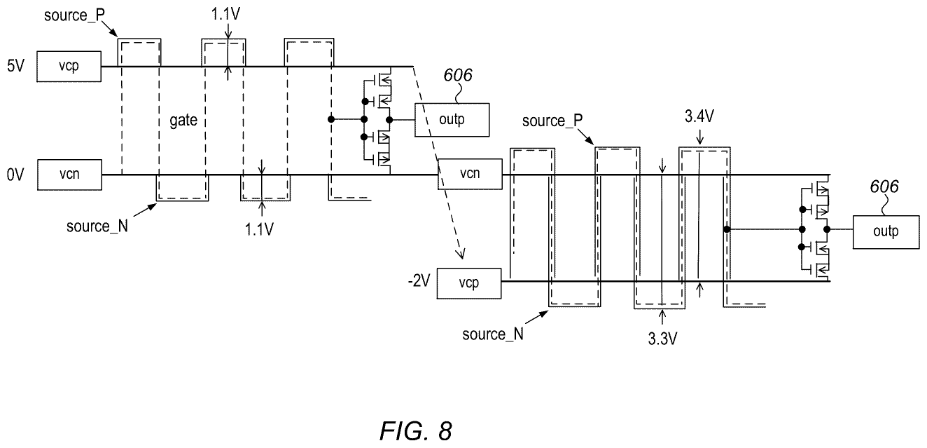

Operation of the HVIF of FIGS. 6A and 6B will now be described with reference to FIGS. 7A, 7B, and 8. FIG. 7A is a timing diagram illustrating operation of the HVIF in the ΔΣADC of FIG. 1 for an input battery voltage V_{BAT} in of 5V, and FIG. 7B is a timing diagram illustrating operation of the HVIF 600 in the ΔΣADC of FIG. 1 for a battery voltage V_{BAT} in of −2V. FIG. 8 is a timing diagram illustrating charge-pump outputs for the HVIF 600 operating at V_{BAT} of 5V and −2V.

Referring to FIG. 7A, at a first time of about 1.1 mS a VBAT of 5V is applied to the vcp and vcn inputs of the HVIF 600 with a vcp of 15V and a vcn of 10V. A charge-pump clock signal (CP clock) of 5V at 100 KHz is applied to first and second charge-pumps 604, 606, beginning at a second time of about 1.11 mS, and the first charge-pump is operated to generate a voltage of about 1.1V raising or increasing source_P to a voltage of about 16.1V by a third time of about 1.14 mS, while the second charge-pump is operated to generate a voltage of about −1.1V decreasing source_N to a voltage of about 8.9V in the same time. The output node (outp) of the HVIF 600 begins outputting an output signal with a peak to peak voltage of about 5V at the same frequency but opposite in phase to the CP clock signal.

Referring to FIG. 7B, for a VBAT of −2V a vcp of about 8V and a vcn of about 10V is applied to the vcp and vcn inputs of the HVIF 600 at a time of 1.1 mS. A charge-pump clock signal (CP clock) of 5V at 100 KHz is applied to first and second charge-pumps 604, 606, beginning at a second time of about 1.11 mS, and the first charge-pump is operated to generate a voltage of about 3.4V raising or increasing source_P to a voltage of about 11.4V by a third time of about 1.14 mS, while the second charge-pump is operated to generate a voltage of about −3.3V decreasing source_N to a voltage of about 6.7V in the same time. The output node (outp) of the HVIF 600 begins outputting an output signal with a peak to peak voltage of about 5V at the same frequency but opposite in phase to the CP clock signal.

Referring to a left side of FIG. 8 for the HVIF 600operating at V_{BAT} of 5V with a vcp of 5V and a vcn of 0V the first charge-pump 604 operates with an output of 1.1V to generate a source_P voltage alternating between 5V and 6.1V, and the second charge-pump 606 operates with an output of −1.1V to generate a source_N voltage alternating between 0V and −1.1V. A gate signal (gate) to the transistors (Q3a, Q3b, Q4a, Q4b) of output stage 608 alternates between source_P and source_N. Because transistors Q1B and Q2B of the limiting circuit 612a, 612b are fully on, the limiting voltage is one times a threshold voltage (vth) of Q1B and Q2B, and a device withstand voltage of transistors in the HVIF 600, and the ΔΣADC 100, is not exceeded.

Referring to a right side of FIG. 8 for the HVIF 600 operating at V_{BAT} of −2V with a vcp of 0V and a vcn of −2V the first charge-pump 604 operates with an output of 3.4V to generate a source_P voltage alternating between −2V and 1.4V, and the second charge-pump 606 operates with an output of −3.3V to generate a source_N voltage alternating between 0V and −3.3V. A gate signal (gate) to the transistors (Q3a, Q3b, Q4a, Q4b) of output stage 608 alternates between source_P and source_N. Because transistors Q1B and Q2B of the limiting circuit 612a, 612b are in source-follower state the limiting voltage is equal to a sum of −2V and twice the threshold voltage (vth) of the transistors, or about 3.3V.

The ΔΣADC and method of the present disclosure provide a high effective number of bits (ENOB) and throughput, while minimizing potential electromagnetic compatibility (EMC) issues and reducing area required for implantation in an integrated circuit (IC), making the ΔΣADC particularly useful in an integrated battery management system (BMS) configured to monitor voltages of a plurality of battery cells connected in series.

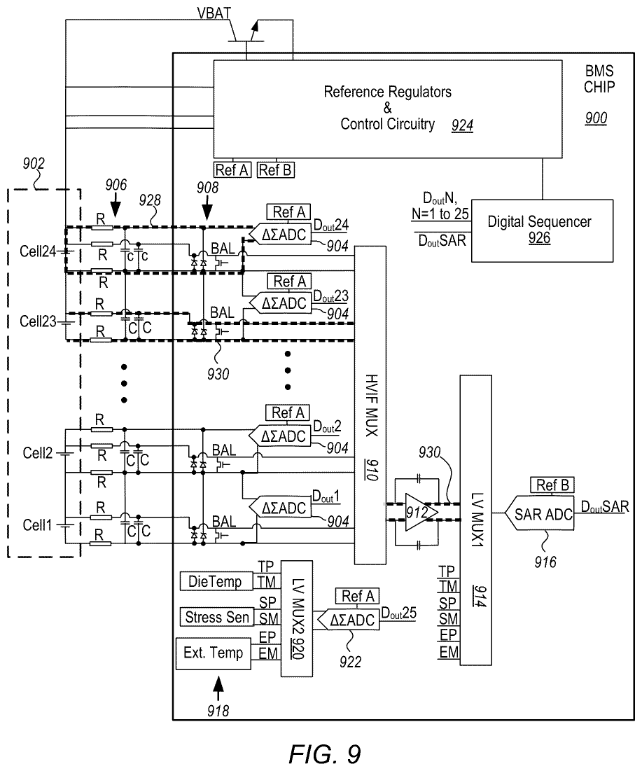

FIG. 9 is a block diagram illustrating a block diagram of a portion of battery management system (BMS 900) for monitoring and managing a battery pack 902, the BMS including a number of second order ΔΣADCs 904 according to an embodiment of the present invention. Referring to FIG. 9, in the embodiment shown, the battery pack 902 includes, for example, 24 lithium ion battery cells (cell 1 to cell 24) of about five (5) volts each for a total battery voltage of about 120 VDC. The battery pack is coupled to the BMS through a filter network 906 including one analog resistor-capacitor filter for each of the battery cells.

The BMS 900 is integrally formed on a single integrated circuit (IC) chip, and includes a balancing network 908 through which each of the analog filters in the filter network 906 and an associated battery cell (cell 1 to cell 24) of the battery pack 902 are coupled to one of the ΔΣADCs 904. The BMS 900 further includes a high voltage interface multiplexer (HVIF MUX 910) with inputs coupled to each of the battery cells through the filter network 906 and an output coupled through a scaling amplifier 912 to a first low voltage multiplexer (LVMUX1 914), and through the LVMUX1 coupled to a successive approximation register analog-to-digital converter (SARADC 916). In some embodiments, such as that shown the BMS 900 further includes a number of sensors 918 to sense, for example, die temperature (Die Temp), die stress (Stress Sen) and external temperature (Ext. Temp), coupled through a second low voltage multiplexer (LVMUX2 920), and through the LVMUX2 coupled to an additional ΔΣADC 922. Additionally, the BMS 900 further includes reference regulators and control circuitry 924 to provide reference voltages (Ref A, Ref B) to the ADCs 904, 916, and 922, and to provide control signals (S1, S2, . . . S21) to the ADCs and multiplexers, and a digital sequencer 926 to receive multibit digital outputs (DₒᵤₜN, N=1 to 25) from the ADCs.

The filter network 906, balancing network 908 each of the ΔΣADCs 904 form one of a number of first or main cell voltage measurement paths 928 for each of the battery cells. Additionally, each of the battery cells is coupled through the filter network 906 and balancing network 908 to the HVIF MUX 912, and through the scaling amplifier 914 and LVMUX 916 to the SAR_ADC 918, to form a number of second or diagnostic voltage measurement paths 930 for each of the battery cells.

During normal operation, the control circuitry 924 operates the filter network 906, balancing network 908, and each of the ΔΣADCs 904 to form a number of main measurement path 928, then operates each ΔΣADC to produce a digital value associated with the sampled analog voltage at the input, using a combination of oversampling and noise shaping techniques as described above.

During diagnostic operations, control circuitry 924 configures HVIF MUX 912 to select a diagnostic voltage measurement paths 930 associated with a particular battery cell (e.g., cell1), and configures the scaling amplifier 914 and LVMUX 916 to measure the voltage across the particular battery cell using the SAR_ADC 918. Typically, the SAR_ADC 918 includes a multibit digital-to-analog-converter (DAC) and integrator, and samples and holds the analog input voltage, and then generates a voltage with the DAC and compares the voltage generated with the voltage sampled at the input using the integrator. The sequence is repeated for all battery cells of the battery pack 902. As SAR_ADCs and their use in measuring analog voltage are well known in the art their operation will not be discussed further.

Since voltage measurements of the battery pack 902 involves sequentially repeating the above steps for each of the battery cells voltage measurements made using the SAR_ADC 918 are much slower, and are used only diagnostically to verify the measurements taken along the main measurement path 928.

Thus, a ΔΣADC including a second order Delta-Sigma-Modulator with first and second integrator stages operable to isolate variations in input common mode voltage, and an input stage operable to perform correlated double sampling (CDS) chopping to reduce offset and flicker noise, have been disclosed. Embodiments of the present invention have been described above with the aid of functional and schematic block diagrams illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention.

It is to be understood that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The breadth and scope of the present invention should not be limited by any of the above-described exemplary embodiments, but should be defined only in accordance with the following claims and their equivalents.

What is claimed is:

1. An Analog-to-Digital Converter (ADC) comprising:
an input stage operable to receive an analog input voltage (V_{IN});
a second order Delta-Sigma-Modulator (2^{nd} order DSM) coupled to the input stage, the second order DSM including a first integrator stage and a second integrator stage coupled in a cascade architecture; and
a quantizer coupled to an output of the 2^{nd} order DSM operable to receive an output from the 2^{nd} order DSM and to produce a multi-bit digital signal.

2. The ADC of claim 1 wherein the ADC has a fully differential architecture with the input stage coupling a positive input voltage (Vp) and a negative input voltage (Vn) to an integrator in the first integrator stage, the first integrator stage coupling a first positive output signal (op1) and a first negative output signal (on1) to a second integrator in the second integrator stage, and the second integrator stage coupling a second positive output signal (op2) and a second negative output signal (on2) to the quantizer.

3. The ADC of claim 2 wherein the fully differential architecture of the ADC is operable to minimize potential Electromagnetic compatibility (EMC) issues.

4. The ADC of claim 2 wherein the first integrator stage is operable to perform correlated double sampling on the positive input voltage (Vp) and the negative input voltage (Vn).

5. The ADC of claim 4 wherein the first integrator stage is operable to double the analog input voltage (V_{IN}).

6. The ADC of claim 4 wherein the first integrator stage and the second integrator stage each comprise a common mode voltage (vcm) input, and are operable to isolate variations in an input common mode voltage.

7. The ADC of claim 4 wherein the first integrator stage comprises a chopping circuit, and is operable to remove any residual offset in the analog input voltage (V_{IN}) coupled from the input stage to the first integrator stage.

8. The ADC of claim 1 wherein the input stage comprises a high voltage interface.

9. A battery management system (BMS) configured to monitor voltages of a plurality of battery cells connected in series, the BMS comprising:
for each of the battery cells a main-cell-measuring-path including an analog-to-digital converter (ADC) comprising:
an input stage operable to receive an analog input voltage (V_{IN});
a second order Delta-Sigma-Modulator (2^{nd} order DSM) coupled to the input stage, the second order DSM including a first integrator stage and a second integrator stage coupled in a cascade architecture; and
a quantizer coupled to an output of the 2^{nd} order DSM operable to receive an output from the 2^{nd} order DSM and to produce a multi-bit digital signal.

10. The BMS of claim 9 wherein the ADC has a fully differential architecture with the input stage coupling a positive input voltage (Vp) and a negative input voltage (Vn) to an integrator in the first integrator stage, the first integrator stage coupling a first positive output signal (op1) and a first negative output signal (on1) to a second integrator in the second integrator stage, and the second integrator stage coupling a second positive output signal (op2) and a second negative output signal (on2) to the quantizer.

11. The BMS of claim 10 wherein the fully differential architecture of the ADC is operable to minimize potential Electromagnetic compatibility (EMC) issues.

12. The BMS of claim 10 wherein the first integrator stage is operable to perform correlated double sampling on the positive input voltage (Vp) and the negative input voltage (Vn).

13. The BMS of claim 12 wherein the first integrator stage is operable to double the analog input voltage (V_{IN}).

14. The BMS of claim 12 wherein the first integrator stage and the second integrator stage each comprise a common mode voltage (vcm) input, and are operable to block a common mode voltage coupled from the input stage.

15. The BMS of claim 12 wherein the first integrator stage comprises a chopping circuit, and is operable to remove any residual offset in the analog input voltage (V_{IN}) coupled from the input stage to the first integrator stage.

16. The BMS of claim 10 wherein the input stage comprises a high voltage interface.

17. A method for operating an analog-to-digital-converter (ADC), comprising:
receiving an analog input voltage (V_{IN}) in an input stage in the ADC;
coupling V_{IN} to a second order Delta-Sigma-Modulator (2^{nd} order DSM) in the ADC;
integrating V_{IN} using a first integrator stage in the 2^{nd} order DSM to generate a first integration of V_{IN};
coupling the first integration of V_{IN} to a second integrator stage in the 2^{nd} order DSM coupled in a cascade architecture with the first integrator stage;
integrating the first integration of V_{IN} using the second integrator stage to generate a second integration of V_{IN};
coupling the second integration of V_{IN} from an output of the 2^{nd} order DSM to a quantizer in the ADC; and
performing quantization of the second integration of V_{IN} to generate a multi-bit digital signal representative of V_{IN}.

18. The method of claim 17 wherein the ADC has a fully differential architecture, and wherein:
receiving V_{IN} in the input stage comprises receiving a positive input voltage (Vp) and a negative input voltage (Vn) and performing correlated double sampling on Vp and Vn;
coupling V_{IN} to the 2nd order DSM comprises coupling Vp and Vn to an integrator in the first integrator stage;
coupling the first integration of V_{IN} to the second integrator stage comprises coupling a first positive output signal (op1) and a first negative output signal (on1) to a second integrator in the second integrator stage; and
coupling the second integration of V_{IN} to the quantizer comprises coupling a second positive output signal (op2) and a second negative output signal (on2) to the quantizer.

19. The method of claim 18 wherein the first integrator stage and the second integrator stage each comprise a common mode voltage (vcm) input, and wherein integrating V_{IN} in the first integrator stage and integrating the first integration of V_{IN} in the second integration stage comprises removing the common mode voltage coupled from the input.

20. The method of claim 18 wherein the first integrator stage comprises a chopping circuit, and coupling V_{IN} to the 2^{nd} order DSM comprises operating the chopping circuit to remove any residual offset in V_{IN} coupled from the input stage to the first integrator stage.
